(19) United States
(12) Patent Application Publication
(10) Pub. No.: US 2024/0414900 A1
(43) Pub. Date: Dec. 12, 2024

(54) Screen Protector for Attenuating Electromagnetic Radiation

(71) Applicant: Dongguan Yulong Optoelectronics Co. Ltd, Dongguan (CN)

(72) Inventors: Song Nam Park, Dongguan (CN); Baorui Tan, Dongguan (CN)

(21) Appl. No.: 18/805,873

(22) Filed: Aug. 15, 2024

(30) Foreign Application Priority Data
Jul. 9, 2024 (CN) 2024216171860

(51) Int. Cl. H05K 9/00; G02B 1/11

(52) U.S. Cl. CPC H05K 9/0054; G02B 1/11

(57) ABSTRACT

The present utility model discloses a screen protector for attenuating electromagnetic radiation, which comprises a protector body and at least one magnetically absorbed piece; the magnetically absorbed piece is intended to attach the protector body to an electronic device screen; the protector body comprises at least one anti-glare sheet and at least one functional film set on one side of the anti-glare sheet through a main body adhesive layer; the magnetically absorbed piece comprises at least one shielding layer, at least one auxiliary attaching part attached to one side of the shielding layer and a first adhesive attaching part set on the other side of the shielding layer; the shielding layer is intended to attach to the electronic device screen in conjunction with the protector body to attenuate the electromagnetic wave intensity of the electronic device; the magnetically absorbed piece is attached to at least one edge of the anti-glare sheet through a first adhesive attaching part; the present utility model is easy to use, assemble and disassemble, reusable and convenient for daily cleaning, improving the attachment stability between the utility model and electronic device screens and reducing the impact of electromagnetic radiation on the human body.

### FIELD OF THE UTILITY MODEL

The present utility model relates to the technical field of screen protectors, particularly to a screen protector that improves the attachment stability to electronic device screens, is reusable and can effectively attenuate electromagnetic radiation.

### BACKGROUND OF THE UTILITY MODEL

Screen protectors, also known as screen decoration films, are cold-mounting films for mounting on electronic device screen surface, which, generally, is intended to effectively prevent screen surfaces from external damages, fingerprints and dirt. Some protectors can also be used for protecting eyesight and reducing sight problems. These screen protectors can usually be attached to electronic device screens through adhesive, electrostatic or magnetic methods; and currently, electrostatic or magnetic methods are popular for screen protector attachment.

For a protector requiring electrostatic attachment, it relies entirely on the static electricity for attachment to a laptop screen; however, the adhesion is limited. When the laptop is opened, its protector may detach from the screen due to poor adhesion, or static electricity on the keyboard side of the laptop, affecting the user's experience.

For a traditional protector requiring magnetic attachment, manganese steel sheets are used as magnetic elements. They can be embedded into prepared PC sheet slots, and then fixed with ornaments. The manganese steel sheets for the products with such structure can be cut by laser; however, the overall thickness is relatively high after assembly. If used for a laptop screen, when the laptop is closed, a big gap between the laptop screen and keyboard will be left, affecting the normal close of the laptop screen and preventing the laptop from entering its standby mode normally. In addition, manganese steel sheets are relatively hard, and if the user accidentally bends the protector, the manganese steel sheets may pierce their ornaments, affecting the normal use of the protector.

Furthermore, for protectors requiring magnetic attachment, 304 stainless steel sheets are also used as magnetic elements. Though having a certain “magnetic attachment” effect, they can be cut by cutting dies rather than laser. However, this material can cause significant wear on the cutting dies. Cutting dies should be replaced frequently in order to ensure normal processing progress, moreover, the processing accuracy of cutting dies is low, which makes processed magnetic elements prone to improper assembly, causing a high product defect rate.

In addition, with the development of society and the advancement of technology, electronic communication devices such as mobile phones, laptops and tablet PCs are increasingly inseparable from people's lives. As is well known, these electronic communication devices are electromagnetic radiation sources that people can come into contact with in daily lives. Common electromagnetic radiation frequency bands for electronic communication devices include radio frequency radiation (RF) and extremely low frequency radiation (ELF), both of which are known as non-ionizing radiation; Wi-Fi and Bluetooth work within frequency bands of 2.4 GHz and 5 GHz, and the electromagnetic radiation is kept below 6 GHz, so they are covered within radio frequency radiation (RF). When measuring at a distance of about 1 m and Wi-Fi is used for data transmission, the RF radiation intensity is usually kept within 30˜50 dBμV/m; when using Bluetooth normally, the RF radiation intensity is usually kept within 20˜40 dBμV/m; Extremely low frequency radiation (ELF) mainly comes from electromagnetic fields generated by electronic components such as power converters and processors of devices during operation. The generated ELF radiation is also much lower than 6 GHz, and the ELF radiation intensity is usually kept within 10˜25 dBμV/m; However, current screen protectors, whether they are adhesive, electrostatic or magnetic product, can not shield these non ionizing radiation items.

### DESCRIPTION OF THE UTILITY MODEL

The present utility model aims to overcome the shortcomings of the prior art and provide a screen protector for attenuating electromagnetic radiation. The screen protector is easy to use and assemble/disassemble, reusable and convenient for daily cleaning, improving the attachment stability between the utility model and electronic device screens, effectively provide a high electromagnetic wave attenuation efficiency for electronic devices and reduce the impact of electromagnetic radiation on the human body.

The present utility model is subject to the following technical solution for serving the above purpose:

A screen protector for attenuating electromagnetic radiation, which comprises a protector body and at least one magnetically absorbed piece; the magnetically absorbed piece is intended to attach the protector body to an electronic device screen; the protector body comprises at least one anti-glare sheet and at least one functional film set on one side of the anti-glare sheet through a main body adhesive layer; the magnetically absorbed piece comprises at least one shielding layer, at least one auxiliary attaching part attached to one side of the shielding layer and a first adhesive attaching part set on the other side of the shielding layer; the shielding layer is intended to attach to the electronic device screen in conjunction with the protector body to attenuate the electromagnetic wave intensity of the electronic device; the magnetically absorbed piece is attached to at least one edge of the anti-glare sheet through a first adhesive attaching part.

Where, the anti-glare sheet is composed of a first anti-glare base layer and a first anti-glare coating applied to one side of the first anti-glare base layer, and the other side of the first anti-glare base layer is attached to the main body adhesive layer.

Where, one side of the functional film is provided with at least one functional coat, and the other side of the functional film is attached to the main body adhesive layer; the functional film can be an anti-peeping substrate, a paper-like base layer, an anti-reflection base layer, or a second anti-glare base layer.

Furthermore, the functional coating is a third anti-glare coating applied to an anti-peeping substrate, or the functional coating is a paper-like coating applied to a paper-like base layer, or the functional coating is an anti-reflection coating applied to an anti-reflection base layer, or the functional coating is a second anti-glare coating applied to a second anti-glare base layer.

Furthermore, the functional coating is a structural layer applied with silver ion coating intended to make screens antibacterial.

Where, the main body adhesive layer is an optical adhesive layer, the thickness of the main body adhesive layer is 10 μm˜60 μm, and the light transmittance is more than 90%.

When only one magnetically absorbed piece with a linear structure is used, it is attached to one edge of the anti-glare sheet through the first adhesive attaching part; or when only one magnetically absorbed piece with a circular structure is used, it is set around the four edges of the anti-glare sheet; or when two magnetically absorbed pieces are used, they are respectively set on two opposing edges of the anti-glare sheet; or when more than two magnetically absorbed pieces are used, they are spaced on at least one edge of the anti-glare sheet through the first adhesive attaching part.

Furthermore, the protector body is provided with a protector through-hole or a protector cut at the position corresponding to the camera of an electronic device screen, and when only one magnetically absorbed piece is used, it is provided with a first through-hole or a first cut corresponding to the protector through-hole or protector cut; when two or more magnetically absorbed pieces are used, they are distributed on at least two sides of the protector through-hole or protector cut.

Where, the shielding layer is a structure pressed from Fe-containing polymer, and the shielding layer is 10 μm˜200 μm thick.

Where, the auxiliary attaching part comprises a first attaching substrate and a first self-restoring material layer applied to one side of the first attaching substrate, and the other side of the first attaching substrate is attached to the shielding layer through a composite adhesive part.

Furthermore, the first attaching substrate is transparent and 10 μm˜50 μm thick, and the first self-restoring material layer is 10 μm˜50 μm thick.

Furthermore, the composite adhesive part is a composite base layer with at least one first adhesive layer on both sides; one first adhesive layer is attached to the shielding layer, and the other first adhesive layer is attached to the first attaching substrate; the composite adhesive part is 10 μm˜50 μm thick.

Or, the auxiliary attaching part is composed of a second attaching substrate, fourth adhesive layers respectively applied to both sides of the second attaching substrate and a foam absorbing layer attached to one of the fourth adhesive layers; the other fourth adhesive layer is attached to the shielding layer.

Furthermore, the second attaching substrate, fourth adhesive layer and foam absorbing layer are 10 μm to 50 μm, 10 μm to 25 μm thick and 100 μm˜200 μm, respectively.

Where, the first adhesive attaching part is an attaching base layer respectively applied with at least one second adhesive layer and one third adhesive layer on both sides, the attaching base layer is 10 μm˜50 μm thick, the second adhesive layer is attached to the shielding layer, and the third adhesive layer is attached to the anti-glare sheet.

When a magnetically absorbed piece is set on one edge of the anti-glare sheet of the protector body, at least one sticking piece is also set on the opposite edge of the anti-glare sheet; the sticking piece is intended to help the magnetically absorbed piece to attach the protector body to an electronic device screen.

Furthermore, the sticking piece comprises a sticking substrate, at least one silicone layer set on one side of the sticking substrate, and at least one second self-restoring material layer set on the other side of the sticking substrate; the silicone layer is attached to the anti-glare sheet, and the sticking substrate, silicone layer and self-restoring material layer are 10 μm˜100 μm, 10 μm˜50 μm and 10 μm˜50 μm thick, respectively.

In addition, at least one ornament is provided on the functional film of the protector body corresponding to the position of the magnetically absorbed piece; the ornament is intend to decorate the setting position of the magnetically absorbed piece.

Furthermore, the ornament comprises a decorative layer and an attaching layer applied to at least one side of the decorative layer, the attaching layer is intended to help the decorative layer to attach to the other side of the protector body; the decorative layer and attaching layer are 10 μm˜80 μm and 10 μm˜50 μm thick, respectively.

The beneficial effects of the present utility model are that it can help to attach a protector body to an electronic device screen through the shielding layer of a magnetically absorbed piece set on at least one edge of the protector body and the magnetic action with magnetic elements in the electronic device screen, which, combined with the auxiliary attaching part adhesion of the magnetically absorbed piece, the attachment stability between the protector body and the electronic device screen can be improved, effectively solving the problem of unstable attachment between traditional protectors and electronic device screens; moreover, the protector body is attached to the electronic device screen through the magnetic effect between the magnetically absorbed piece and the magnetic elements of the electronic device screen, making it more convenient to disassemble and assemble the protector body from the electronic device screen, achieving the purpose of reusability; the shielding layer of the magnetically absorbed piece is a structure made of pressed Fe-containing polymer, which can achieve a high electromagnetic wave attenuation efficiency for electronic devices and reduce the impact of electromagnetic radiation on the human body; when a magnetically absorbed piece is set on one edge of the protector body and a sticking piece is set on the opposite edge of the protector body, the second self-restoring material layer of the sticking piece can effectively help the magnetically absorbed piece to attach the protector body to the electronic device screen; for the present utility model, the ornament on the protector body can effectively enhance the decorative effect of electronic device screens; the surface of the protector body, magnetically absorbed piece, or sticking piece can be cleaned with water, making the daily cleaning of the present utility model more convenient; in addition, the material selection of magnetically absorbed pieces makes all components of the present utility model directly cuttable by laser, effectively eliminating defects such as “significant wear on cutting dies”, “low processing accuracy”, “high product defect rate” when the components are process with cutting dies, greatly improving the product accuracy; moreover, the accuracy improvement of each component also makes the product assembly easier; for example, for the assembly between a protector body and a magnetically absorbed piece, only standard assembly fixtures are required: Place the magnetically absorbed piece in the corresponding slot for the magnetically absorbed piece with an assembly fixture, make the first adhesive attaching part of the magnetically absorbed piece face upward; then, place the anti-glare sheet of the protector body towards the assembly fixture, so that the anti-glare sheet can come into contact with the first adhesive attaching part; then exert a slight force to the position where the protector body contacts the first adhesive attaching part, the protector body can be attached to the magnetically absorbed piece easily; then exert a slight force to the position where the protector body contacts the first adhesive attaching part, the protector body can be attached to the magnetically absorbed piece easily; due to the high precision of each component, the size consistency of each component at the corresponding attachment position can be effectively ensured, greatly improving the pass rate of products.

### DESCRIPTION OF THE DRAWINGS

FIG. 1 shows the Exploded 3D Structure Diagram I of Embodiment 1 for the present utility model.

FIG. 2 shows the Exploded 3D Structure Diagram II of Embodiment 1 for the present utility model.

FIG. 3 shows the Exploded 3D Structure Diagram III of Embodiment 1 for the present utility model.

FIG. 4 shows the Exploded 3D Structure Diagram IV of Embodiment 1 for the present utility model.

FIG. 5 shows the Exploded 3D Structure Diagram V of Embodiment 1 for the present utility model.

FIG. 6 shows the Exploded 3D Structure Diagram VI of Embodiment 1 for the present utility model.

FIG. 7 shows the Exploded 3D Structure Diagram VII of Embodiment 1 for the present utility model.

FIG. 8 shows the Exploded 3D Structure Diagram VIII of Embodiment 1 for the present utility model.

FIG. 9 shows the Exploded 3D Structure Diagram of Embodiment 5 for the present utility model.

FIG. 10 shows the Exploded 3D Structure Diagram I of Embodiment 6 for the present utility model.

FIG. 11 shows the Exploded 3D Structure Diagram II of Embodiment 6 for the present utility model.

FIG. 12 shows the sectional schematic diagram of Embodiment 6 for the present utility model.

FIG. 13 shows the protector body structure diagram of Embodiment 1 for the present utility model.

FIG. 14 shows the protector body structure diagram of Embodiment 2 for the present utility model.

FIG. 15 shows the protector body structure diagram of Embodiment 3 for the present utility model.

FIG. 16 shows the protector body structure diagram of Embodiment 4 for the present utility model.

FIG. 17 shows the Structure Diagram I of the magnetically absorbed piece for the present utility model.

FIG. 18 shows the Structure Diagram II of the magnetically absorbed piece for the present utility model.

FIG. 19 shows the structure diagram of the sticking piece for the present utility model.

FIG. 20 shows the structure diagram of the ornament for the present utility model.

### EXPLANATION OF DRAWING MARKS

1—Protector body; 11—Anti-glare sheet; 111—First anti-glare base layer; 112—First anti-glare coat; 12—Main body adhesive layer; 13—Functional film; 131—Anti-peeping substrate; 132—Paper-like base layer; 133—Anti-reflection base layer; 134—Second anti-glare base layer; 14—Functional coat; 141—Third anti-glare coat; 142—Paper-like coat; 143—Anti-reflection coat; 144—Second anti-glare coat; 1a—Protector through-hole; 1b—Protector cut; 2—magnetically absorbed piece; 21—Shielding layer; 22—Auxiliary attaching part; 23—First adhesive attaching part; 221—First attaching substrate; 222—First self-restoring material layer; 223—Composite adhesive part; 223a—First adhesive layer; 223b—Composite base layer; 22a—Second attaching substrate; 22b—Fourth adhesive layer; 22c—Foam absorbing layer; 231—Second adhesive layer; 232—Third adhesive layer; 233—Attaching base layer; 2a—First through-hole; 2b—First cut; 3—Sticking piece; 31—Sticking substrate; 32—Silicone layer; 33—Second self-restoring material layer; 4—Ornament; 41—Decorative layer; 42—Attaching layer; 4a—Second through-hole; 4b—Second cut.

### DETAILED DESCRIPTION OF THE EMBODIMENTS

The following provides a further description of the present utility model through detailed embodiments and according to the drawings of the specification:

### Detailed Embodiment 1

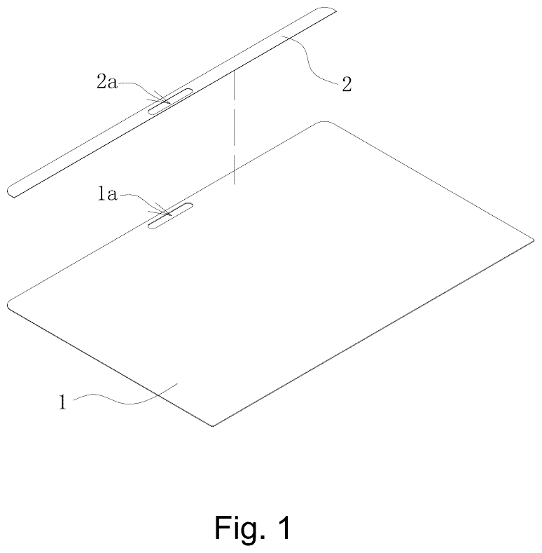

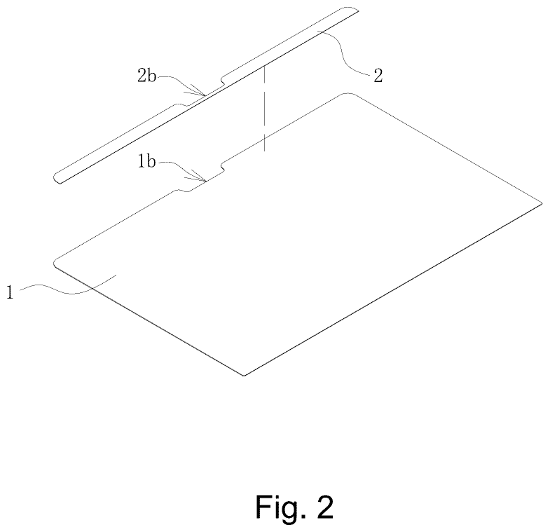

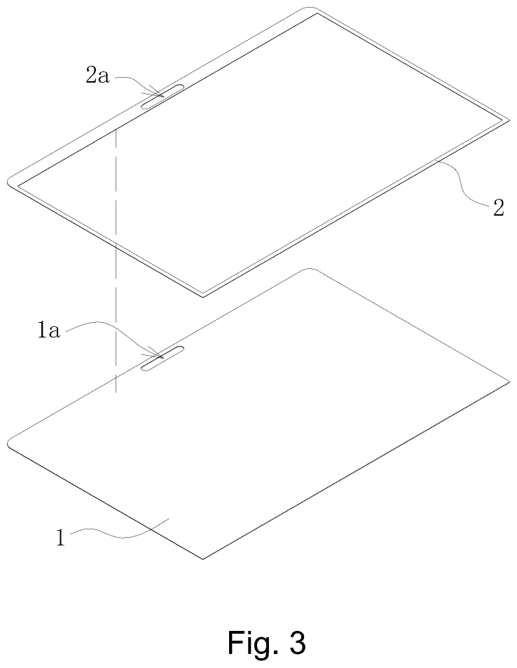

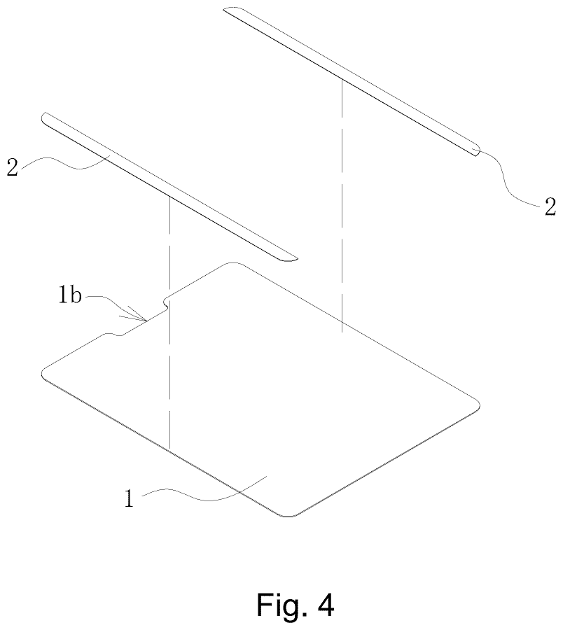

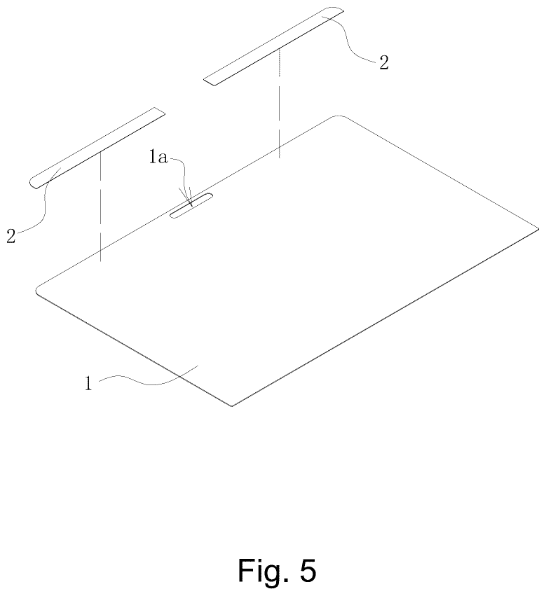

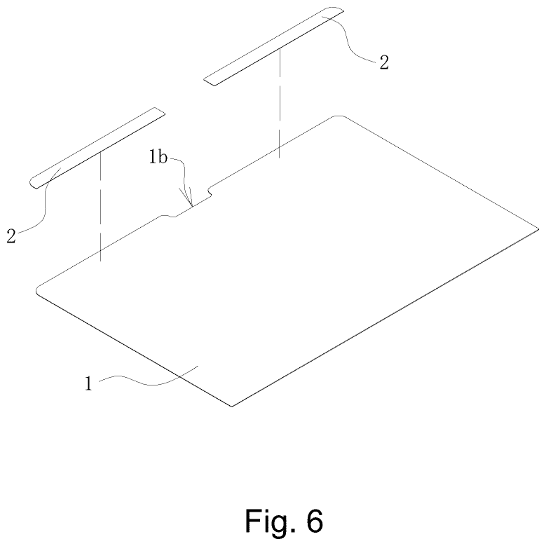

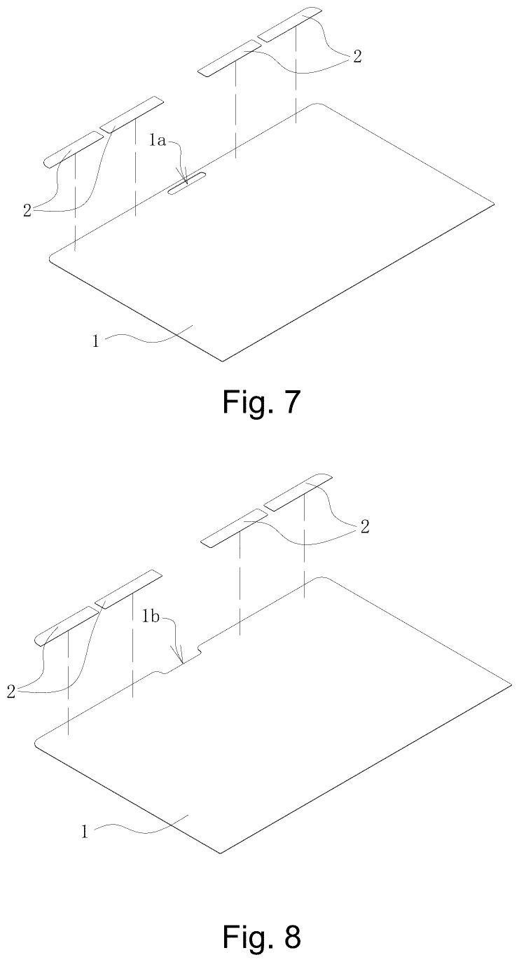

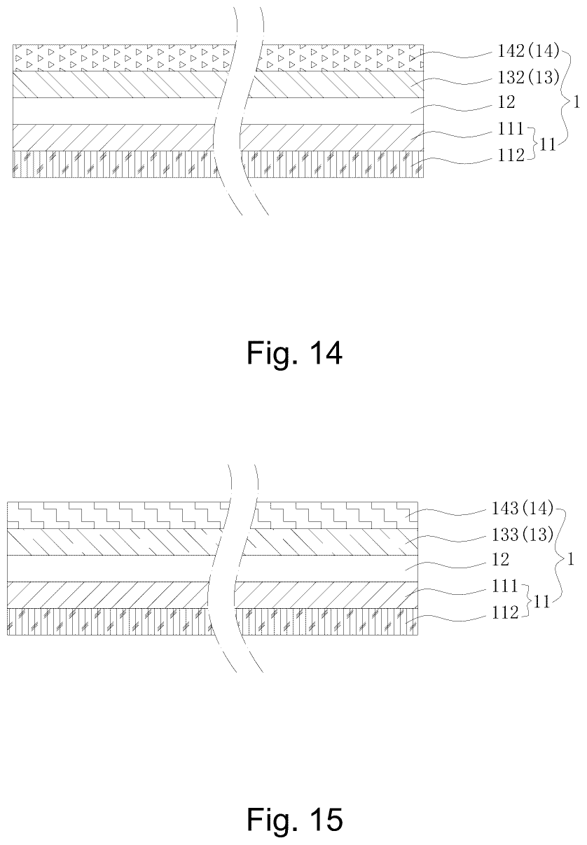

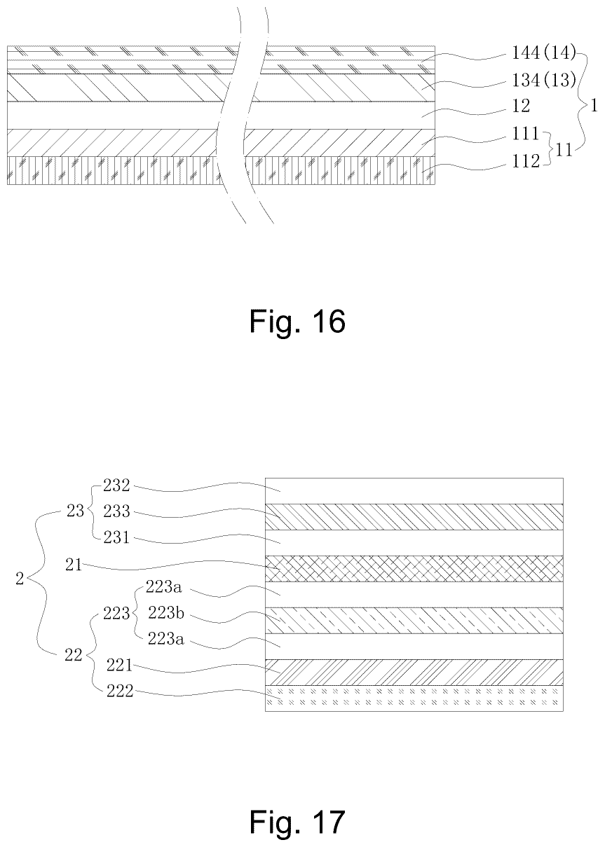

As shown in FIGS. 1-20, the present utility model relates to a screen protector for attenuating electromagnetic radiation, which comprises a protector body 1 and at least one magnetically absorbed piece 2; the magnetically absorbed piece 2 is intended to attach the protector body 1 to an electronic device screen; the protector body 1 comprises at least one anti-glare sheet 11 and at least one functional film 13 set on one side of the anti-glare sheet 11 through a main body adhesive layer 12; the magnetically absorbed piece 2 comprises at least one shielding layer 21, at least one auxiliary attaching part 22 attached to one side of the shielding layer 21 and a first adhesive attaching part 23 set on the other side of the shielding layer 21; the shielding layer 21 is intended to attach to the electronic device screen in conjunction with the protector body 1 to attenuate the electromagnetic wave intensity of the electronic device; the magnetically absorbed piece 2 is attached to at least one edge of the anti-glare sheet 11 through a first adhesive attaching part 23;

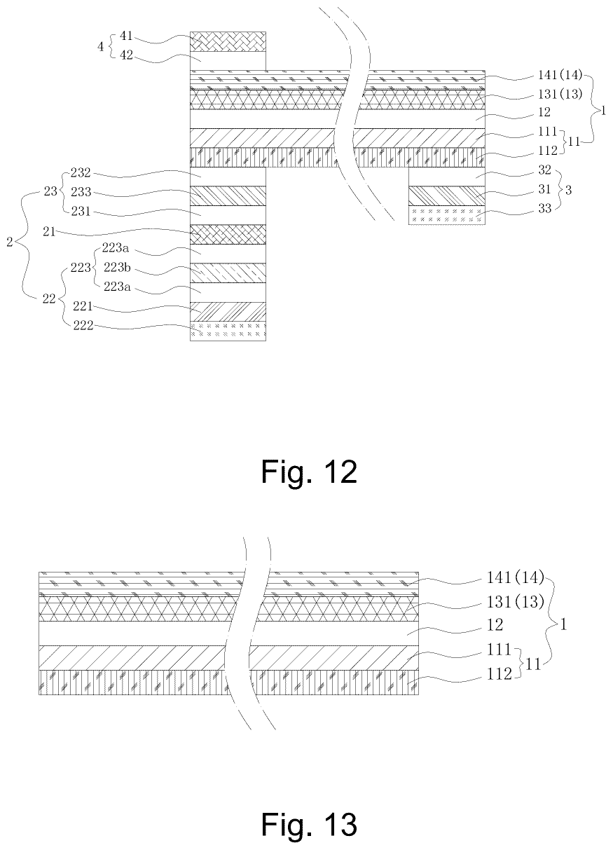

As shown in FIGS. 12-16, the anti-glare sheet 11 is composed of a first anti-glare base layer 111 and a first anti-glare coating 112 applied to one side of the first anti-glare base layer 111, and the other side of the first anti-glare base layer 111 is attached to the main body adhesive layer 12; the first anti-glare base layer 111 is a transparent PET; the first anti-glare base layer 111 is 125±1 μm thick; the first anti-glare coating 112 is a structure applied with AG anti-glare coating; the first anti-glare coating 112 is 3˜5 um thick; when the present utility model is attached to an electronic device screen, the anti-glare sheet 11 can achieve a better contact with the electronic device screen through the first anti-glare coating 112, effectively preventing the generation of Newton rings.

As shown in FIGS. 12-16, one side of the functional film 13 is provided with at least one functional coating 14, and the other side of the functional film 13 is attached to the main body adhesive layer 12; when the functional film 13 is an anti-peeping substrate 131, the anti-peeping substrate 131 can be used to prevent people other than the user from peeking at the content displayed on the electronic device screen; the anti-peeping substrate 131 is 100˜350 μm thick.

Furthermore, as shown in FIGS. 12-16, the functional coating 14 is a third anti-glare coating 141 applied to the anti-peeping substrate 131; the third anti-glare coating 141 is a structure formed by applying AG anti-glare coating on the anti-peeping substrate 131; the third anti-glare coating 141 is 3˜5 um thick, and its haze ratio is 30%; the third anti-glare coating 141 is characterized by high friction resistance, fine particle size without obvious flash points, and excellent anti-glare effect.

Furthermore, the functional coating 14 is a structural layer coated with silver ion coating, which is intended to enhance the antibacterial effect of the screen; specifically, when the functional coating 14 is a third anti-glare coating 141, the silver ion coating is an AG anti-glare coating with 0.5˜10% silver ions added; the added silver ions make the functional coating 14 antibacterial, because silver ions are an inorganic antibacterial substance that can be firmly adsorbed onto cell membranes relying on Coulomb attraction and penetrate cell walls to enter into cells, causing protein coagulation and even death of cells due to failed division and proliferation; in addition, silver ions can also damage the microbial electronic transport system, respiratory system and material transport system; when bacterial cells lose their activity, silver ions will be dissociated from the cells and repeat their sterilization and, accordingly, they can be used for long-lasting sterilization.

As shown in FIGS. 12-16, the main body adhesive layer 12 is an optical adhesive layer, the thickness of the main body adhesive layer 12 is 10 μm˜60 μm, the light transmittance is more than 90%, and the adhesion force higher than 1000 g/inch; specifically, the main body adhesive layer 12 is a structure applied with OCA (acrylic adhesive) on an anti-glare sheet 11; when the anti-peeping substrate 131, main body adhesive layer 12 and anti-glare sheet 11 are combined, the main body adhesive layer 12 can be effectively filled into the diamond-shaped structural layer of the anti-peeping substrate 131, effectively improving the composite effect between the anti-peeping substrate 131 and anti-glare sheet 11 and making the composite structure between the anti-peeping substrate 131 and anti-glare sheet 11 more stable.

As shown in FIGS. 1-12, 17 and 18, when only one magnetically absorbed piece 2 is used and the magnetically absorbed piece 2 is a linear structure, the magnetically absorbed piece 2 is attached to one edge of the anti-glare sheet 11 through the first adhesive attaching part 23; or when only one magnetically absorbed piece 2 is used and the magnetically absorbed piece 2 is a circular structure, the magnetically absorbed piece 2 is set around the four edges of the anti-glare sheet 11; or when two magnetically absorbed pieces 2 are used, the magnetically absorbed pieces 2 are respectively set on two edges of the anti-glare sheet 11 opposing to each other; or when more than two magnetically absorbed pieces 2 are used, the magnetically absorbed pieces 2 are spaced on at least one edge of the anti-glare sheet 11 through the first adhesive attaching part 23.

Furthermore, as shown in FIGS. 1-11, the protector body 1 is provided with a protector through-hole 1a or a protector cut 1b at the position corresponding to the camera of an electronic device screen, and when only one magnetically absorbed piece 2 is used, the magnetically absorbed piece 2 is provided with a first through-hole 2a or a first cut 2b corresponding to the protector through-hole 1a or protector cut 1b; when two or more magnetically absorbed pieces 2 are used, the magnetically absorbed pieces 2 are distributed on at least two sides of the protector through-hole 1a or protector cut 1b.

As shown in FIGS. 12, 17 and 18, the shielding layer 21 is a structure made of pressed Fe-containing polymer, and the thickness of the shielding layer 21 is kept within 10 μm˜200 μm; the shielding layer 21 is a sheet structure made by mixing 2D magnetic powder (such as ferrite or magnetic iron nanomaterials) with neoprene and foam plastics, and the Fe content in the shielding layer 21 is 65˜85%; generally, the electromagnetic radiation frequency of electronic devices such as laptops or tablet PCs is mainly below 6 GHz and their electromagnetic radiation intensity is 20˜50 dBμV/m; according to current test results, 2D magnetic powder and 30% silicone can be used as attaching pieces and pressed into 0.1 mm thick shielding sheets; the shielding effectiveness of the shielding sheets is between 20-40 dB for 1-6 GHz frequency bands; it can be seen that the ferrite or magnetic iron nanomaterials used in the shielding layer 21 can have a high electromagnetic wave attenuation efficiency within a frequency range below 6 GHz; for screens of electronic devices such as laptops or tablet PCs, magnetic elements such as magnetic switches are generally provided; the combination of these magnetic elements and the shielding layer 21 of the magnetically absorbed piece 2 for the present utility model has a magnetic effect, which can help to magnetically attach the protector body 1 to an electronic device screen.

As shown in FIGS. 12 and 17, the auxiliary attaching part 22 includes a first attaching substrate 221 and a first self-restoring material layer 222 coated on one side of the first attaching substrate 221; the other side of the first attaching substrate 221 is attached to the shielding layer 21 through a composite adhesive part 223; the first attaching substrate 221 is a transparent PET substrate with a thickness of 10 μm˜50 μm; the first attaching substrate 221 is the base material for the first self-restoring material layer 222, and the thickness of the first self-restoring material layer 222 is 10 μm˜50 μm; the adhesion force of the first self-restoring material layer 222 is 10˜30 g/inch; the main component of the first self-restoring material layer 222 is polyurethane, which, as a polymer with a self-restoring property, can help to achieve self-restoring molecularly when being damaged; the first self-restoring material layer 222 of the auxiliary attaching part 22 can be effectively used in conjunction with the shielding layer 21 through a certain adhesion force to improve the attachment stability between the protector body 1 and electronic device screens; the polyurethane can be washed with water, making the cleaning of this utility model more convenient.

As shown in FIGS. 12 and 17, the composite adhesive part 223 is a composite base layer 223b coated with at least one first adhesive layer 223a on both sides; one first adhesive layer 223a is attached to the shielding layer 21, and the other first adhesive layer 223a is attached to the first attaching substrate 221; the composite adhesive part 223 is 10 μm˜50 μm thick; the composite base layer 223b is a black PE substrate, and the thickness of the composite base layer 223b is 12±1 μm; the main component of the first adhesive layer 223a is acrylic polymer, and the thickness of the first adhesive layer 223a is 9±1 μm; the adhesion force of the first adhesive layer 223a is higher than 800 g/inch.

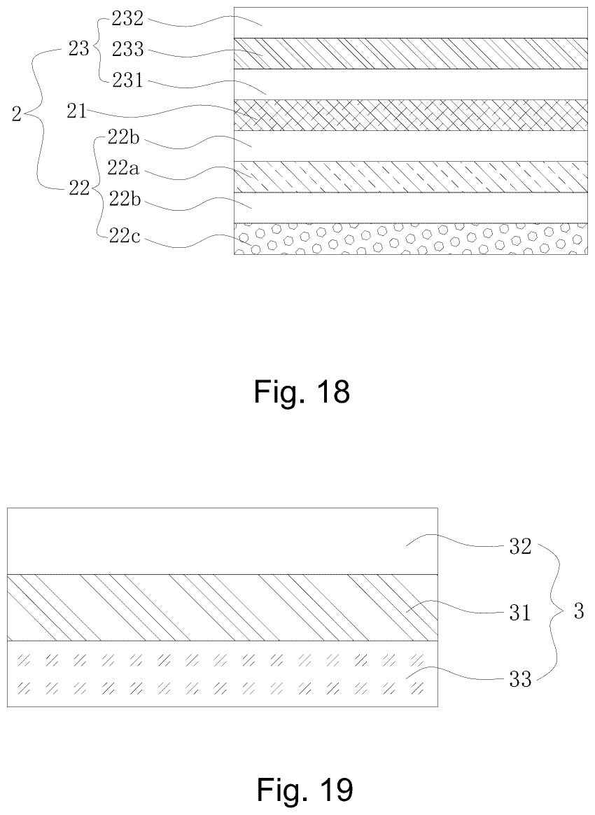

Or, as shown in FIG. 18, the auxiliary attaching part 22 is composed of a second attaching substrate 22a, fourth adhesive layers 22b on both sides of the second attaching substrate 22a and a foam absorbing layer 22c attached to one of the fourth adhesive layers 22b; the other fourth adhesive layer 22b is attached to the shielding layer 21; the total thickness of the auxiliary attaching part 22 is 10˜300 μm; the second attaching substrate 22a and fourth adhesive layer 22b are 10 μm˜50 μm and 10 μm˜25 μm, respectively; the adhesion force of the fourth adhesive layer 22b is higher than 800 g/inch; the foam absorbing layer 22c is 100 μm˜200 μm thick; According to the repeated tests on the same material, the average absorption force of the foam absorbing layer 22c is 1.93N/25 mm, which can effectively enhance the attachment effect between the adsorbed piece 2 and electronic device screens; specifically, the foam absorbing layer 22c is preferably made of acrylic foam; the acrylic foam is excellent in adsorption and can be stably fixed on smooth surfaces such as glass; specifically, when the foam absorbing layer 22c is pressed by an external force, the air in the foam absorbing layer 22c can be discharged, making the foam absorbing layer 22c, like a suction cup, has an adsorption effect on electronic device screens; especially, for plastic side frames of some electronic device screens, the foam absorbing layer 22c can be embedded into plastic part surfaces when pressed by an external force; therefore, the foam absorbing layer 22c of the auxiliary attaching part 22 can be effectively used in conjunction with the shielding layer 21, improving the attachment stability between the protector body 1 and electronic device screens; in addition, the acrylic foam can be washed with water, making the cleaning of the present utility model more convenient.

Furthermore, for electronic devices without magnetic elements locally or wholly, the present utility model with a foam absorbing layer 22c should be preferred; when selected, just align the edge of the protector body 1 with that of an electronic device screen and press the foam absorbing layer 22c to discharge the air from the foam absorbing layer 22c, the utility model can be effectively and stably attached to the screen/screen frame of the electronic device.

As shown in FIGS. 12, 17 and 18, the first adhesive attaching part 23 is an attaching base layer 233 coated with at least one second adhesive layer 231 and a third adhesive layer 232 on both sides; the attaching base layer 233 is a black PET substrate and the thickness of the attaching base layer is 10 μm˜50 μm; the second adhesive layer 231 is attached to the shielding layer 21, and the third adhesive layer 232 is attached to the anti-glare sheet 11; the main component of the second adhesive layer 231 is acrylic acid polymer, thickness and adhesion force are 16±1 μm and 1700 g/inch, respectively; the main component of the third adhesive layer 232 is acrylic acid polymer, the thickness and adhesion force are 19±1 μm and 1900 g/inch, respectively.

Before use, the present utility model that matches the target electronic device screen should be selected; after selection, just make the upper edge of the protector body 1 for the present utility model close to that of the electronic device screen to produce a magnetic effect between the magnetically absorbed piece 2 and the magnetic elements of the electronic device screen; when the magnetically absorbed piece 2 works, align the other edges of the protector body 1 with those of the screen to make the protector body 1 be completely attached to the electronic device screen; then gently press the magnetically absorbed piece 2 at the protector body 1 to make the auxiliary attaching part 22 of the magnetically absorbed piece 2 further adhere to the electronic device screen and accordingly improve the attachment stability between the present utility model and the electronic device screen.

If the present utility model needs to be removed, just pinch the protector body 1 from one of the upper corners of the protector body 1 for the utility model, and gradually separate the protector body 1 from the screen along the edge of the electronic device, thus the utility model can be easily and completely removed from the electronic device screen; the utility model completely removed from the electronic device screen can be wiped or cleaned with water, dried and carefully placed in a container for future use.

### Detailed Embodiment 2

As shown in FIGS. 1-11 and 14, the present utility model discloses a screen protector for attenuating electromagnetic radiation; when the functional film 13 is a paper-like base layer 132, its functional coating 14 is a paper-like coating 142 applied to the paper-like substrate 132; the paper-like base layer 132 is 100 μm±5 μm thick, and the preferred material for the paper-like base layer 132 is transparent PET; the main component of the paper-like coating 142 is acrylic acid polymer, and the thickness of the paper-like coating 142 is 10 μm±5 μm; The haze ratio of the paper-like coating 142 is 15±5, and the light transmittance of the paper-like coating 142 is over 89%; when the paper-like coating 142 can provide users with a damping sensation similar to writing on a piece of paper when they come into contact with the protector body 1, obtaining an experience similar to writing on a piece of paper.

Furthermore, when the functional coating 14 of this embodiment is a paper-like coating 142, the silver ion coating forming the paper-like coating 142 mainly contains acrylic acid polymer with 0.5˜10% silver ions added; the added silver ions make the functional coating 14 antibacterial; other technical characters not mentioned in this embodiment can be explained based on those in Embodiment 1 and therefore will not be repeated here.

### Detailed Embodiment 3

As shown in FIGS. 1-11 and 15, the present utility model discloses a screen protector for attenuating electromagnetic radiation; when the functional film 13 is an anti-reflection base layer 133, its functional coating 14 is an anti-reflection coating 143 applied to the anti-reflection base layer 133; the anti-reflection base layer 133 is 100 μm±5 μm thick, and the anti-reflection base layer 133 is preferably made of transparent PET; the main component of the anti-reflection coating 143 is acrylic acid polymer, and the anti-reflection coating 143 is 10 μm±5 μm; the haze ratio of the anti-reflection coating 143 is 15±5, and the light transmittance of the anti-reflection coating 143 is over 89%.

Furthermore, when the functional coating 14 of this embodiment is an anti-reflection coating 143, the silver ion coating forming the anti-reflection coating 143 mainly contains acrylic acid polymer with 0.5˜10% silver ions added; the added silver ions make the functional coating 14 antibacterial; other technical characters not mentioned in this embodiment can be explained based on those in Embodiment 1 and therefore will not be repeated here.

### Detailed Embodiment 4

As shown in FIGS. 1-11 and 16, the present utility model discloses a screen protector for attenuating electromagnetic radiation; when its functional film 13 is a second anti-glare base layer 134, its functional coating 14 is a second anti-glare coating 144 applied to the second anti-glare base layer 134; the second anti-glare base layer 134 is 100 μm±5 μm thick, and the second anti-glare base layer 134 is preferably made of transparent PET; the second anti-glare coating 144 is a structure applied with AG anti-glare coating; the second anti-glare coating 144 is 10 μm±5 μm thick; the haze ratio of the second anti-glare coating 144 is 15±5, and the light transmittance of the second anti-glare coating 144 is over 89%.

Furthermore, when the functional coating 14 of this embodiment is a second anti-glare coating 144, the silver ion coating forming the second anti-glare coating 144 is AG anti-glare coating with 0.5˜10% silver ions added; the added silver ions make the functional coating 14 antibacterial; other technical characters not mentioned in this embodiment can be explained based on those in Embodiment 1 and therefore will not be repeated here.

### Detailed Embodiment 5

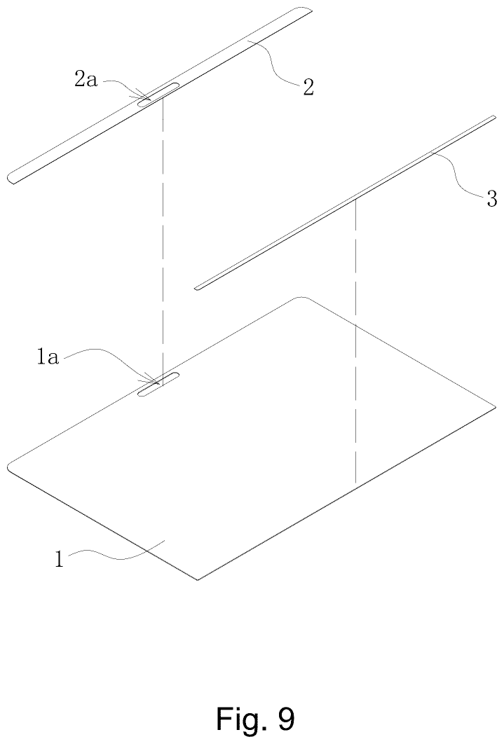

As shown in FIGS. 9-12 and 19, the present utility model discloses a screen protector for attenuating electromagnetic radiation; when a magnetically absorbed piece 2 is set on one edge of the anti-glare sheet 11 of the protector body 1, at least one sticking piece 3 is also set on the opposite edge of the anti-glare sheet 11; the sticking piece 3 is intended to help the magnetically absorbed piece 2 to attach the protector body to an electronic device screen.

Furthermore, as shown in FIGS. 12 and 19, the sticking piece 3 comprises a sticking substrate 31, at least one silicone layer 32 applied to one side of the sticking substrate 31, and at least one second self-restoring material layer 33 applied to the other side of the sticking substrate 31; the silicone layer 32 is attached to the anti-glare sheet 11, the sticking substrate 31 is a black PET substrate, the sticking substrate 31 is 10 μm˜100 μm thick, the silicone layer 32 is 10 μm˜50 μm thick, the second self-restoring material layer 33 is 10 μm˜50 μm thick, and the adhesion force of the second self-restoring material layer 33 is higher than 15 g/inch; The main component of the second self-restoring material layer 33 is polyurethane, which, as a polymer with a self-restoring property, can help to achieve self-restoring molecularly when being damaged; the second self-restoring layer 33 of the auxiliary attaching part 22 can be effectively used in conjunction with the magnetically absorbed piece 2 through a certain adhesion force to improve the attachment between the protector body 1 and electronic device screens; the polyurethane can be washed with water, making the cleaning of this utility model more convenient.

After selecting and attaching the present utility model to an electronic device screen, gently press the sticking piece 3 on the protector body 1 to further adhere the second self-restoring material layer 33 on the sticking piece 3 to the electronic device screen to improve the attachment stability between the present utility model and electronic device screen.

Other technical characters not mentioned in this embodiment can be explained based on those in Embodiment 1 and therefore will not be repeated here.

### Detailed Embodiment 6

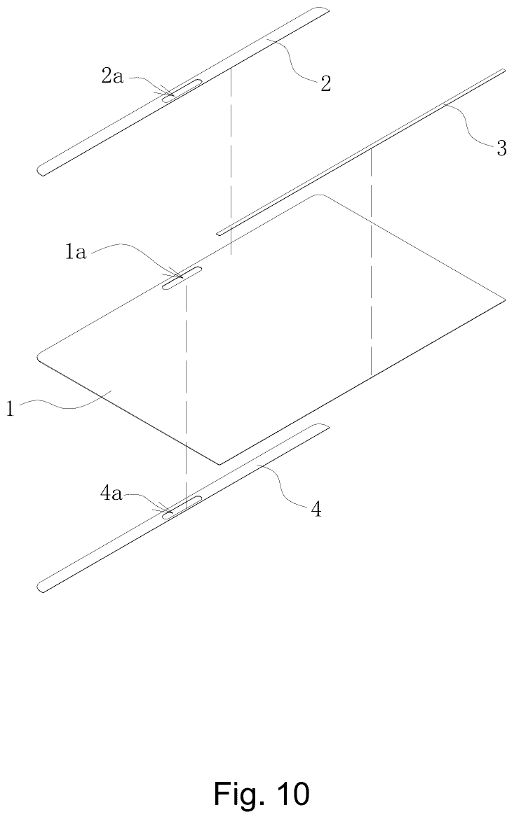

As shown in FIGS. 10-12 and 20, the present utility model discloses a screen protector for attenuating electromagnetic radiation, at least one ornament 4 is provided on the functional film 13 of the protector body 1 corresponding to the position of the magnetically absorbed piece; the ornament 4 is intended to decorate the setting position of the magnetically absorbed piece 2.

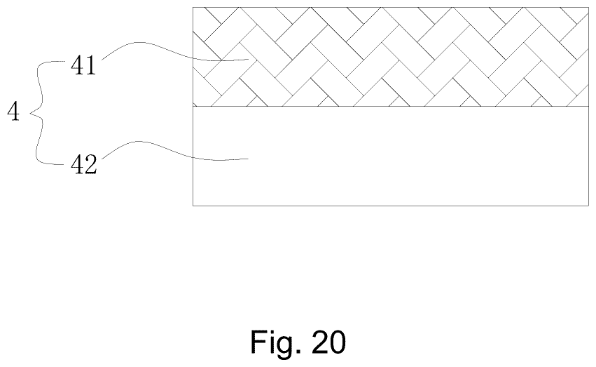

As shown in FIGS. 12 and 20, the ornament 4 comprises a decorative layer 41 and an attaching layer 42 applied to at least one side of the decorative layer 41; the attaching layer 42 is intended to attach to the other side of the protector body 1 in conjunction with the decorative layer 41; the decorative layer 41 and attaching layer 42 are 10 μm˜80 μm and 10 μm˜50 μm thick, respectively; the adhesion force of the attaching layer 42 is higher than 1000 g/inch; the decorative layer 41 is preferably made of PC sheets, PET sheets, filmed paper or other decorative materials; when the decorative layer 41 made of PC sheets or PET sheets is selected, PC sheets or PET sheets with different colors can be used to achieve the desired decorative effect; when the decorative layer 41 is made of filmed paper, various patterns can be printed on the decorative layer 41 to enhance the decorative effect of the present utility model; the decorative materials of the decorative layer 41 can be dependent on the actual decorative requirements of products and are not limited here.

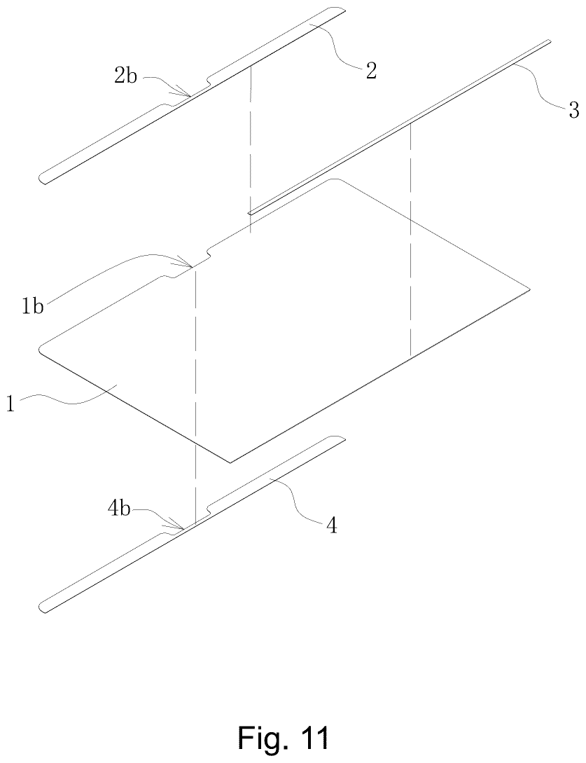

As shown in FIGS. 10-11, when the ornament 4 is set at the edge of the protector body 1 with a protector through-hole 1a or a protector cut 1, and only one ornament 4 is used, the magnetically absorbed piece 2 corresponding to the protector through-hole 1a or protector cut 1b is provided with a second through-hole 4a or a second cut 4b; When two or more ornaments 4 are used, each ornament 4 are distributed on at least two sides of the protector through-hole 1a or protector cut 1b.

Other technical characters not mentioned in this embodiment can be explained based on those in any one of Embodiment 1-5 and therefore will not be repeated here.

The above description relates only to preferred embodiments of the present utility model and does not limit the scope of the present utility model. Therefore, within the design spirit of the present utility model, equivalent changes or decorations made by those skilled in the art to the structure, features and principles described in the present utility model should fall within protection of the patent application for the present utility model.

1. A screen protector for attenuating electromagnetic radiation, which comprises a protector body and at least one magnetically absorbed piece; the magnetically absorbed piece is intended to attach the protector body to an electronic device screen, which is characterized in that the protector body comprises at least one anti-glare sheet and at least one functional film set on one side of the anti-glare sheet through a main body adhesive layer; the magnetically absorbed piece comprises at least one shielding layer, at least one auxiliary attaching part attached to one side of the shielding layer and a first adhesive attaching part set on the other side of the shielding layer; the shielding layer is intended to attach to the electronic device screen in conjunction with the protector body to attenuate the electromagnetic wave intensity of the electronic device; the magnetically absorbed piece is attached to at least one edge of the anti-glare sheet through a first adhesive attaching part.

2. The screen protector for attenuating electromagnetic radiation according to claim 1, which is characterized in that the anti-glare sheet is composed of a first anti-glare base layer and a first anti-glare coating applied to one side of the first anti-glare base layer, and the other side of the first anti-glare base layer is attached to the main body adhesive layer.

3. The screen protector for attenuating electromagnetic radiation according to claim 1, which is characterized in that one side of the functional film is provided with at least one functional coating, and the other side of the functional film is attached to the main body adhesive layer; the functional film can be an anti-peeping substrate, a paper-like base layer, an anti-reflection base layer, or a second anti-glare base layer.

4. The screen protector for attenuating electromagnetic radiation according to claim 3, which is characterized in that the functional coating is a third anti-glare coating applied to an anti-peeping substrate, or the functional coating is a paper-like coating applied to a paper-like base layer, or the functional coating is an anti-reflection coating applied to an anti-reflection base layer, or the functional coating is a second anti-glare coating applied to a second anti-glare base layer.

5. The screen protector for attenuating electromagnetic radiation according to claim 4, which is characterized in that the functional coating is a structural layer applied with silver ion coating intended to make the screen protector antibacterial.

6. The screen protector for attenuating electromagnetic radiation according to claim 1, which is characterized in that the main body adhesive layer is an optical adhesive layer, the thickness of the main body adhesive layer has a thickness of 10 μm to 60 μm, and the light transmittance is more than 90%.

7. The screen protector for attenuating electromagnetic radiation according to claim 1, which is characterized in that when only one magnetically absorbed piece with a linear structure is used, it is attached to one edge of the anti-glare sheet through the first adhesive attaching part; or when only one magnetically absorbed piece with a circular structure is used, it is set around the four edges of the anti-glare sheet; or when two magnetically absorbed pieces are used, they are respectively set on two opposing edges of the anti-glare sheet; or when more than two magnetically absorbed pieces are used, they are spaced on at least one edge of the anti-glare sheet through the first adhesive attaching part.

8. The screen protector for attenuating electromagnetic radiation according to claim 7, which is characterized in that the protector body is provided with a protector through-hole or a protector cut at the position corresponding to the camera of an electronic device screen, and when only one magnetically absorbed piece is used, it is provided with a first through-hole or a first cut corresponding to the protector through-hole or protector cut; when two or more magnetically absorbed pieces are used, they are distributed on at least two sides of the protector through-hole or protector cut.

9. The screen protector for attenuating electromagnetic radiation according to claim 1, which is characterized in that the shielding layer is a structure pressed from Fe-containing polymer, and the shielding layer is 10 μm˜200 μm thick.

10. The screen protector for attenuating electromagnetic radiation according to claim 1, which is characterized in that the auxiliary attaching part comprises a first attaching substrate and a first self-restoring material layer applied to one side of the first attaching substrate, and the other side of the first attaching substrate is attached to the shielding layer through a composite adhesive part.

11. The screen protector for attenuating electromagnetic radiation according to claim 10, which is characterized in that the first attaching substrate is transparent and 10 μm˜50 μm thick, and the first self-restoring material layer is 10 μm˜50 μm thick.

12. The screen protector for attenuating electromagnetic radiation according to claim 10, which is characterized in that the composite adhesive part is a composite base layer with at least one first adhesive layer on both sides; one first adhesive layer is attached to the shielding layer, and the other first adhesive layer is attached to the first attaching substrate; the composite adhesive part is 10 μm˜50 μm thick.

13. The screen protector for attenuating electromagnetic radiation according to claim 1, which is characterized in that the auxiliary attaching part is composed of a second attaching substrate, fourth adhesive layers respectively applied to both sides of the second attaching substrate, and a foam absorbing layer attached to one of the fourth adhesive layers; the other fourth adhesive layer is attached to the shielding layer.

14. The screen protector for attenuating electromagnetic radiation according to claim 13, which is characterized in that the second attaching substrate, fourth adhesive layer and foam absorbing layer are 10 μm˜50 μm, 10 μm˜25 μm and 100 μm˜200 μm thick, respectively.

15. The screen protector for attenuating electromagnetic radiation according to claim 1, which is characterized in that the first adhesive attaching part is an attaching base layer respectively applied with at least one second adhesive layer and one third adhesive layer on both sides, the attaching base layer is 10 μm˜50 μm thick, the second adhesive layer is attached to the shielding layer, and the third adhesive layer is attached to the anti-glare sheet.

16. The screen protector for attenuating electromagnetic radiation according to claim 1, which is characterized in that when a magnetically absorbed piece is set on one edge of the anti-glare sheet of the protector body, at least one sticking piece is also set on the opposite edge of the anti-glare sheet; the sticking piece is intended to help the magnetically absorbed piece to attach the protector body to an electronic device screen.

17. The screen protector for attenuating electromagnetic radiation according to claim 16, which is characterized in that the sticking piece comprises a sticking substrate, at least one silicone layer set on one side of the sticking substrate, and at least one second self-restoring material layer set on the other side of the sticking substrate; the silicone layer is attached to the anti-glare sheet, and the sticking substrate, silicone layer and self-restoring material layer are 10 μm˜100 μm, 10 μm˜50 μm and 10 μm˜50 μm thick, respectively.

18. The screen protector for attenuating electromagnetic radiation according to claim 1, which is characterized in that at least one ornament is provided on the functional film of the protector body corresponding to the position of the magnetically absorbed piece; the ornament is intended to decorate the setting position of the magnetically absorbed piece.

19. The screen protector for attenuating electromagnetic radiation according to claim 18, which is characterized in that the ornament comprises a decorative layer and an attaching layer applied to at least one side of the decorative layer, the attaching layer is intended to help the decorative layer to attach to the other side of the protector body; the decorative layer and attaching layer are 10 μm˜80 μm and 10 μm˜50 μm thick, respectively.
